(19) United States
(12) Patent Application Publication
(10) Pub. No.: US 2026/0004040 A1
(43) Pub. Date: Jan. 1, 2026

(54) VIRTUAL BRIDGE FOR DESIGN OF AN INTEGRATED CIRCUIT

(71) Applicant: ARTERIS, INC., Campbell, CA (US)

(72) Inventors: Yaron SEMIAT, Paris (FR); Benoit LAFAGE, Les Lilas (FR); Nabil GUISSOUMA, Paris (FR)

(73) Assignee: ARTERIS, INC., Campbell, CA (US)

(21) Appl. No.: 18/759,989

(22) Filed: Jun. 30, 2024

(51) Int. Cl. G06F 30/394; G06F 30/323

(52) U.S. Cl. CPC G06F 30/394; G06F 30/323

(57) ABSTRACT

A computer-aided design method includes accessing an elaborated model of an integrated circuit. The elaborated model includes a first plurality of source buses, a second plurality of addressable components, and a third plurality of interconnections between the source buses and the components. The method further includes generating a canonical model from the elaborated model. The canonical model includes a source bus interface for each one of the source buses and a component interface for each one of the components. The plurality of interconnections between the components and the sources are consolidated. Exports are generated from the canonical model instead of the elaborated model.

### TECHNICAL FIELD

The present technology is in the field of electronic computer-aided design of integrated circuits.

### BACKGROUND

During design of a system-on-chip (SoC) or other modern integrated circuit (IC), a system architect generates a specification that relates to requirements of the integrated circuit. The specification may provide a chip definition, technology, domains and layout for the integrated circuit. An elaborated model of the integrated circuit is then created. Intellectual Property (IP) blocks are selected from the architect's library, configurable components are assembled from the IP blocks, and interconnections are made between the components.

After an initial IC design is generated, the IC design may be modified. Modifications may include adding components, adding instances, removing components, removing instances, changing the hierarchy of instances, changing connectivity between elements, changing parameters of instances, and so on. The modifications may continue until the system architect is satisfied with the architecture.

### SUMMARY

In accordance with various embodiments and aspects herein, a computer-aided design method comprises accessing an elaborated model of an integrated circuit. The elaborated model includes a first plurality of source buses, a second plurality of addressable components, and a third plurality of interconnections between the source buses and the components. The method further includes generating a canonical model from the elaborated model. The canonical model includes a source bus interface for each one of the source buses and a component interface for each one of the components. The plurality of interconnections between the components and the sources are consolidated. Exports are generated from the canonical model instead of the elaborated model.

In accordance with various embodiments and aspects herein, a computer system comprises a processing unit; and computer-readable memory. The computer-readable memory is configured with a tool for causing the processing unit to generate a canonical model of an integrated circuit from an elaborated model of the integrated circuit. The elaborated model includes source buses, addressable components, and interconnections. The canonical model includes a virtual bridge, the source bus interfaces connected to inputs of the virtual bridge; and the addressable components connected to outputs of the virtual bridge. The interconnections in the elaborated model are consolidated into the virtual bridge in the canonical model.

In accordance with various embodiments and aspects herein, an article comprises computer-readable memory encoded with instructions that, when executed, cause a processing unit to create a canonical model of an integrated circuit from an elaborated model of the integrated circuit. The elaborated model includes source buses, addressable components, and interconnections. The canonical model includes a single virtual bridge, the source buses, and the components. Each source bus is connected to an input of the virtual bridge, and each component is connected to an output of the virtual bridge. All of the interconnections in the elaborated model are consolidated into the virtual bridge in the canonical model.

### BRIEF DESCRIPTION OF THE DRAWINGS

In order to understand the invention more fully, reference is made to the accompanying drawings. The invention is described in accordance with the aspects and embodiments in the following description with reference to the drawings or figures (FIG.), in which like numbers represent the same or similar elements. Understanding that these drawings are not to be considered limitations in the scope of the invention, the presently described aspects and embodiments and the presently understood best mode of the invention are described with additional detail through use of the accompanying drawings.

FIG. 1 shows a method for designing an integrated circuit in accordance with various aspects and embodiments herein.

FIG. 2 shows a virtual bridge in accordance with various aspects and embodiments herein.

FIG. 3 shows a method for generating a virtual bridge in accordance with various aspects and embodiments herein.

FIG. 4 shows references from a target bus interface to a component interface in a virtual bridge in accordance with the various aspects and embodiments herein.

FIGS. 5A and 5B illustrate a simple IC design and a virtual bridge during different stages of creation in accordance with the various aspects and embodiments herein.

FIG. 6 shows a computer system programmed with a tool for performing the method of FIG. 3 in accordance with various aspects and embodiments herein.

### DETAILED DESCRIPTION

The following describes various examples of the present technology that illustrate various aspects and embodiments of the invention. Generally, examples can use the described aspects in any combination. All statements herein reciting principles, aspects, and embodiments as well as specific examples thereof, are intended to encompass both structural and functional equivalents thereof. The examples provided are intended as non-limiting examples. Additionally, it is intended that such equivalents include both currently known equivalents and equivalents developed in the future, i.e., any elements developed that perform the same function, regardless of structure.

It is noted that, as used herein, the singular forms “a,” “an” and “the” include plural referents unless the context clearly dictates otherwise. Reference throughout this specification to “one embodiment,” “an embodiment,” “certain embodiment,” “various embodiments,” or similar language means that a particular aspect, feature, structure, or characteristic described in connection with the embodiment is included in at least one embodiment of the invention.

Thus, appearances of the phrases “in one embodiment,” “in at least one embodiment,” “in an embodiment,” “in certain embodiments,” and similar language throughout this specification may, but do not necessarily, all refer to the same embodiment or similar embodiments. Furthermore, aspects and embodiments of the invention described herein are merely exemplary, and should not be construed as limiting of the scope or spirit of the invention as appreciated by those of ordinary skill in the art. The disclosed invention is effectively made or used in any embodiment that includes any novel aspect described herein. All statements herein reciting principles, aspects, and embodiments of the invention are intended to encompass both structural and functional equivalents thereof. It is intended that such equivalents include both currently known equivalents and equivalents developed in the future. Furthermore, to the extent that the terms “including”, “includes”, “having”, “has”, “with”, or variants thereof are used in either the detailed description and the claims, such terms are intended to be inclusive in a similar manner to the term “comprising.”

“IP” or Intellectual Property refers to a reusable unit of logic or functionality or a cell or a layout design. Each IP may have a memory map, hosting registers and memory elements arranged under address blocks. Each memory map is accessible through a bus interface. The IP may be described in one or more IEEE 1685 standard files.

The IEEE 1685 standard describes an XML schema for meta-data documenting IP used in the development, implementation, and verification of electronic systems. Standardized meta-data forms include components, systems, bus interfaces and connections, abstractions of those buses, and details of the components including address maps, register and field descriptions. One such standard is the IP-XACT 1685-2022 standard.

A “component” represents a single IP block that can be instantiated as a single entity in a design. A component document provides information about a component, such as such as interfaces of an IP (e.g., configurable parameters, registers, ports, and grouping of ports into bus interfaces); views of an IP (e.g., RTL and TLM descriptions); and files implementing each view (e.g., Verilog, VHDL, and SystemC files).

As used herein, a “model” or “design” of an integrated circuit refers to the components of the integrated circuit and the interconnections between the components. The design may be represented by IP-XACT files.

A “local memory map” refers to a mapping of addressable memory elements of a component. The local memory map facilities communication between components of a design. It defines memory regions, address ranges, and associated attributes (e.g., read/write permission and data widths). Memory maps may include different types of memory map elements, including registers, address blocks, banks, and subspace maps.

A “bus definition” specifies a type of bus. A bus definition document describes signals in the bus interface and constraints that apply to those signals. This includes signal names, direction, width, and usage.

A “bus interface” references an addressable bus definition to make a link to a component address space. Interface characteristics, including ports, direction (input/output), signals, protocols, address range, and timing constraints can be specified using IP-XACT.

A “transaction” may refer to a request transaction or a response transaction. A transaction may contain one or more destination addresses for one or more components the transaction is sent to. The address may include the address of a sub-component (e.g., an individual register within an array of registers, internal memory, etc.).

A “target bus interface” refers to an interface on which transactions are received.

An “initiator bus interface” refers to an interface on which transactions are sent.

A “bridge” refers to a component that allows access to several memory maps through a single interface.

A “mode configuration” for a path refers to a group of modes that need to be active to go through the path.

The terms “source,” “master,” and “initiator” are used interchangeably within the scope and embodiments of the invention. The terms “sink,” “slave,” and “target” are used interchangeably within the scope and embodiments of the invention.

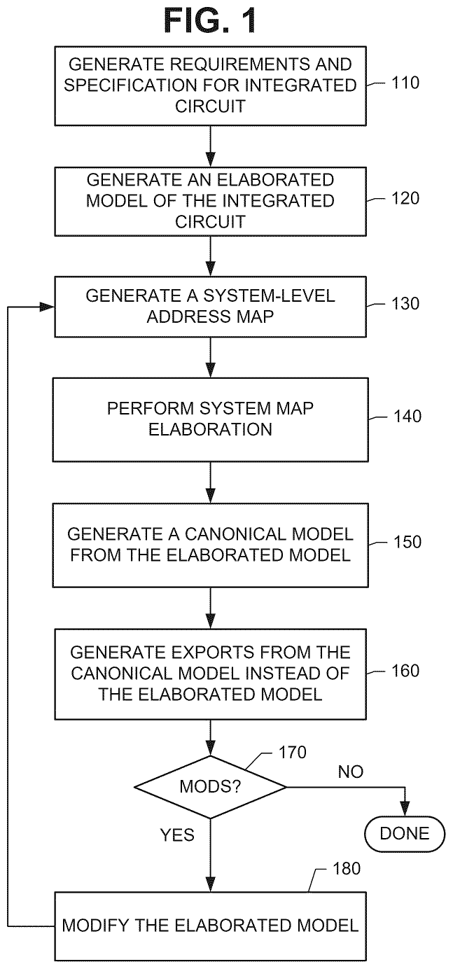

Reference is made to FIG. 1, which illustrates a method of designing an integrated circuit. At block 100, requirements for the integrated circuit are generated. The requirements may be dictated by marketing, sales, customer intent, etc. Also at block 100, a system architect generates a specification that relates to the requirements. The specification provides a chip definition, technology, domains and layout for the integrated circuit.

At block 120, an elaborated model or design of the integrated circuit is created. IP blocks are selected from the architect's library, configurable components are assembled from the IP blocks, interconnections are made between the IP blocks, and parameters of the components are resolved. The interconnections may include wires and bridges. Various routing components (e.g., interconnects and bridges) may be used to route and process transactions between the components. For example, an interconnect can have several input ports for accepting transactions, determining the output port based on address, and modifying the address. As another example, a bridge may have a single input port and a single output port, perform operations on the transaction (e.g., communication protocol conversions, clock conversions, buffering), and modify the address to create a new address for the outgoing transaction.

At block 130, a system-level address map of the design is created. The system-level address map identifies unique memory addresses or unique memory address ranges in the design. An address range may be a contiguous sequence of addresses, with a start address and an end address, from a given initiator (e.g., graphics processor unit, central processing unit), for which transactions using an address in the range go through the same sequence of components and reaches the same target. A system-level address map may be created by looking at address ranges of the initiators in a system. Issuance capabilities may be the number of address bits in a transaction issued by an initiator. Acceptance capabilities may be the number of address bits in the transaction received by a target (e.g., a peripheral component).

Generation of the system-level address map is not limited to any particular method. For example, the system-level address map may be generated as described in US Publication No. 2023/0025288. A tree representation of an integrated circuit is created based on the interconnect of the design. Each port of the design is assigned a tree node. The tree representation may be created using interconnect information where an initiator is a root node, a target is a child node, and each port is a tree node containing information such as hierarchical component identification within the design, local addressable elements, address transfer function, transformations (e.g., masking, clipping, adding offset), local address ranges, capability to perform operations on addresses (e.g., address range), and memory of node (e.g., memory, registers). The information may further include issuance capabilities, acceptance capabilities, and one or more transfer functions from input port to output port(s) (e.g., bridge transfer function, interconnect transfer function, and component transfer function).

The tree representation is traversed from target(s) to initiator(s), calculating the address transformation at each node. By traversing from the target(s) (child node(s)) to the initiator (root node) and applying the respective data models at each step, the path of the system-level address map from the initiator to the target(s) is computed.

At block 140, system map elaboration is performed. The system map elaboration follows the connections of the bus interfaces, and discovers one or more bridges. Connected peripherals may be discovered at the end of these bridges In some instances, there can be part of an address bus that is not connected. This may result in clipping of addresses of a discovered peripheral.

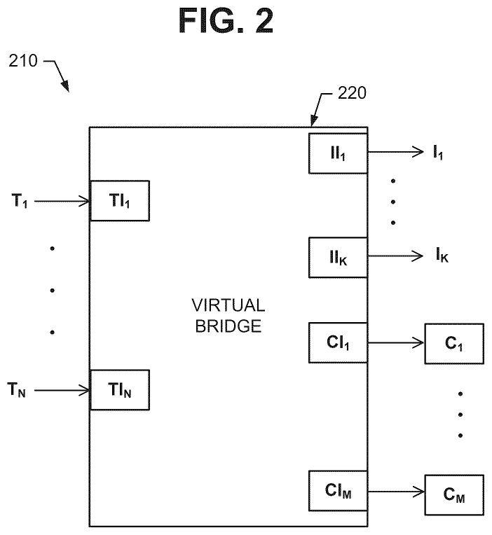

At block 150, a canonical model of the design is generated. The canonical model consolidates all of the interconnections into a single data structure, hereinafter referred to as a “virtual bridge.” A canonical model is illustrated in FIG. 2. A virtual bridge platform 210 identifies all target interfaces T₁ . . . T_{N} in the design, and it identifies all targeted components C₁ . . . C_{M} in the design. A single virtual bridge 220 provides a representation of the interconnections between the target interfaces T₁ . . . T_{N} and the targeted components C₁ . . . C_{M}. The virtual bridge 220 may also identify initiator outputs I₁ . . . I_{K}.

The virtual bridge 220 may include memory map information for each of the source buses T₁ . . . T_{N}, memory map information for each of the targeted components C₁ . . . C_{M}, and memory map information for each of the initiator outputs I₁ . . . I_{K}. Different segments of a memory map may contain information for different modes of operation.

In some embodiments, memory map information includes a component interface CI for each of the targeted components C₁ . . . C_{M}. Each component interface CI may include segments or chunks of memory maps, including range and base address of the corresponding target component. The memory map information further includes an interface TI for each of the source buses. Each source bus interface TI may include references to memory map segments with address offsets and dependencies for different modes. The memory map information may further include an interface II for each of the initiator outputs.

The behavior of each component may be dependent on its modes of operation. For example in low power mode, access to one peripheral is allowed, whereas in full power mode, access to twelve peripherals is allowed. There may be different paths for different modes. One segment might address a portion of logic in a component, whereas another segment might address the full logic of the component. The virtual bridge may represent dependencies on these modes. These are not necessarily all of the possible combinations of modes, but rather a sub-set of modes.

Thus, blocks 110 to 150 take a complex system and produce a simplified presentation that does not include the interconnections. Several advantages flow from this simplified presentation.

At block 160, exports are generated from the virtual bridge platform instead of the design. The exports may include a Register Transfer Level (RTL) design, which may be delivered to a system integrator. In some instances, especially during early stages of IC design, the canonical model may provide sufficient information to a system integrator for prototype RTL design and simulation. This simplified presentation, in turn, reduces computational burden on a computer-aided design system (when compared to creating an RTL design that includes components for the interconnections and performing a simulation of such an RTL design).

The simplified presentation also reduces the volume of information sent to the system integrator. For instance, it simplifies the export of description formats, such as a system-level address map report, C Header files, UVM RAL models and documentation.

The exports may also include a baseline design of the integrated circuit. Further modifications to the design can be compared to the baseline design to determine whether the intent of the design is maintained. The baseline design simplifies the comparison between two IC designs, by bringing each to its virtual bridge presentation. This can be useful for comparing an architecture intent vs design implementation, or for comparing an initial design with a more detailed design.

The canonical model itself may be exported. For instance, the canonical model may be exported to the architect of a network on chip (NoC). A NoC may be used to handle communication between the targeted components. A NoC typically includes network interface units, switches, adapters, buffers and other components. In an SoC or other integrated circuit that implements a NoC, the integrated circuit may include cores that provide data to the NoC, and cores that receive data from the NoC. The NoC sends data from source bus interfaces to targeted components via packet-based transmission using industry-standard protocols.

One example of an IC system is a multiprocessor system that is implemented in SoCs that communicate through a NoC. An initiator, connected to the NoC, sends a request transaction to a target or targets, using an address to select the target or targets. The NoC decodes the address and transports the request from the initiator to the target. The target handles the transaction and sends a response transaction, which is transported back by the NoC to the initiator. As such, the SoC and NoC include complexity and configurability, especially in situation when the NoC is configurable.

During design of an integrated circuit that includes a NoC, the architect of the integrated circuit might identify real estate for the NoC. The NoC architect then designs the NoC to fit within that real estate and provides an RTL design to the system integrator, who integrates the NoC design with other designs in the integrated circuit.

The canonical model offers certain advantages to a NoC architect. It identifies all connections for the NoC architect and eliminates the task of the NoC architect having to ascertain the connections from a model. Thus, the canonical model streamlines the design process of both the NoC and the integrated circuit.

At blocks 170 and 180, the design may be modified. Modifications may include adding components, adding instances, removing components, removing instances, changing the hierarchy of instances, and changing connectivity between components. Modifications may also include changing parameters of the components in the design. Examples include, but are not limited to, size of memory IP, a power domain, a clock domain, size of a port, number of interfaces, clock speed, bandwidth of a component, component storage, and IP configuration.

Modifications may be driven by other considerations. For example, a change may be based on modification flux and/or specific business knowledge.

If it is desired to generate another canonical model after the design has been modified, control is returned to block 130, and a system-level address map and a canonical model are generated from the modified design. Otherwise, the method exits.

The canonical model may be generated algorithmically, or it may be generated by a trained machine learning model that can identify the target interfaces and the targeted components.

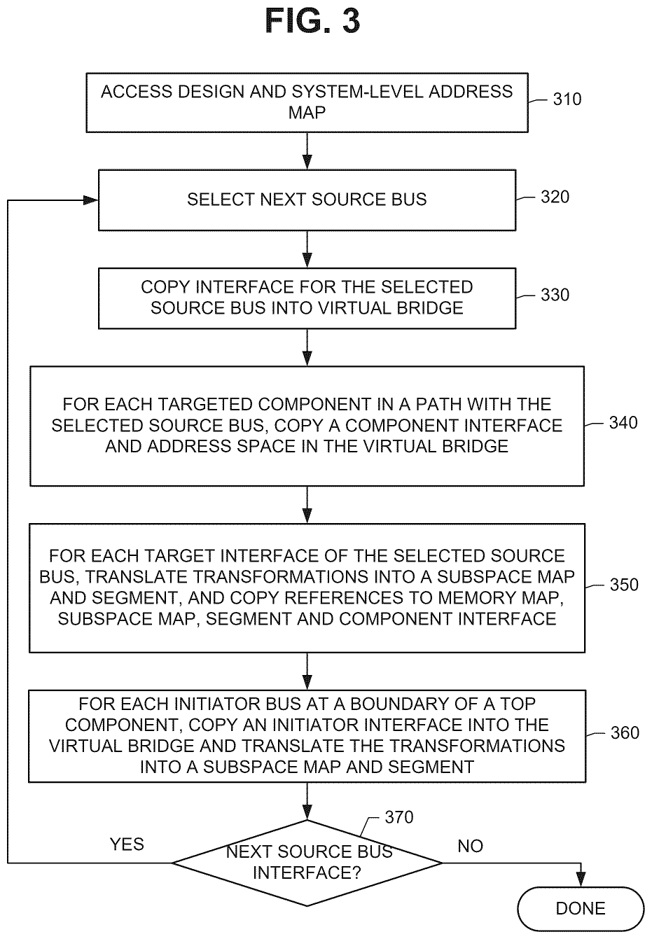

Reference is made to FIG. 3, which illustrates a method for generating the canonical model from an IC design. At block 310, the design and the system-level address map are accessed. At block 320, a source bus is selected.

At block 330, a bus interface for the selected source bus is created in a virtual bridge. If the selected source bus is a target bus, a target bus interface is copied into the virtual bridge. If the source bus has a different interface mode, a new target bus interface having the same bus definition or abstraction definition is copied into the virtual bridge.

At block 340, component interfaces are created in the virtual bus. For each targeted component in a path with the selected source bus, a component interface and address space are created in the virtual bridge. If a component has a transparent bridge that sees a local memory map, the address space range is the last address of the local memory map plus the maximum of address space width or the address space unit bits. Otherwise, the address space range is taken from a system-level address map consolidation including mode maps and local memory maps seen through potential subspace modes. The modes of each component are not taken into account for these transformations since they will only impact the memory map content.

At block 350, transformations for a given component are identified from the system-level address map. The transformations are translated into a subspace map, and a segment of a memory map. References are created in the target bus interface for the selected source bus. The references link each visible path from the target bus interface to the interface of the given component.

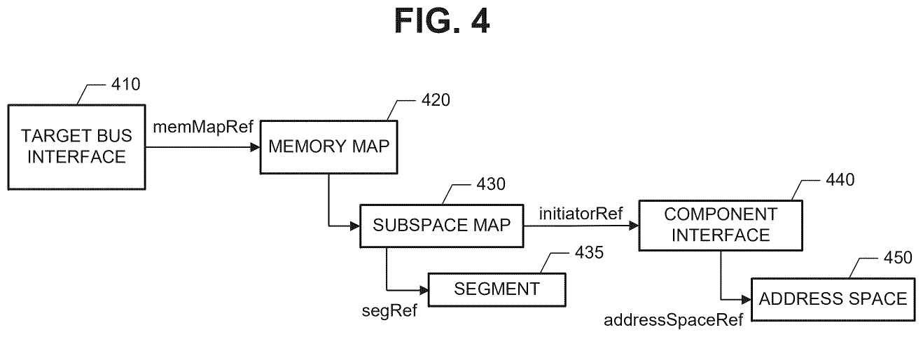

Additional reference is made to FIG. 4, which illustrates how the references are used. A target bus interface 410 references a memory map 420 via a first reference (memMapRef). The memory map 420 contains a subspace map 430, and that subspace map 430 references a component interface 440 via a second reference (initiatorRef). The component interface 440 has an address space 450, which is referenced via a third reference (addressSpaceRef). The subspace map references 430 the segment 435 via a fourth reference (segRef).

If the path depends upon a mode configuration, a mode is created (if that mode has not already been created), a mode map is created, and a subspace map in the mode map is created. Otherwise, a subspace map is created in the memory map. After the transformations have been translated, the subspace map references a possible segment created via segRef.

At block 360, for each initiator bus at the boundary of a top component, an initiator interface is copied into the virtual bridge (unless copied already), and for each possible path from the selected source bus to the initiator bus interface, transformations are translated into a subspace map and a segment. Translating the transformations includes creating an address space and references, creating a segment whose range and offset are taken from a system map consolidation, and creating a subspace map of a memory map (or of a mode map if the path depends a mode configuration). The subspace map references the initiator bus interface via initiatorRef. The subspace map references the segment via segRef.

Multiple source bus interfaces may see the same component interface. They both may also see the same address space and the local memory map.

At block 370, the next source bus interface is selected, so control is returned to block 320. Otherwise, the method is finished.

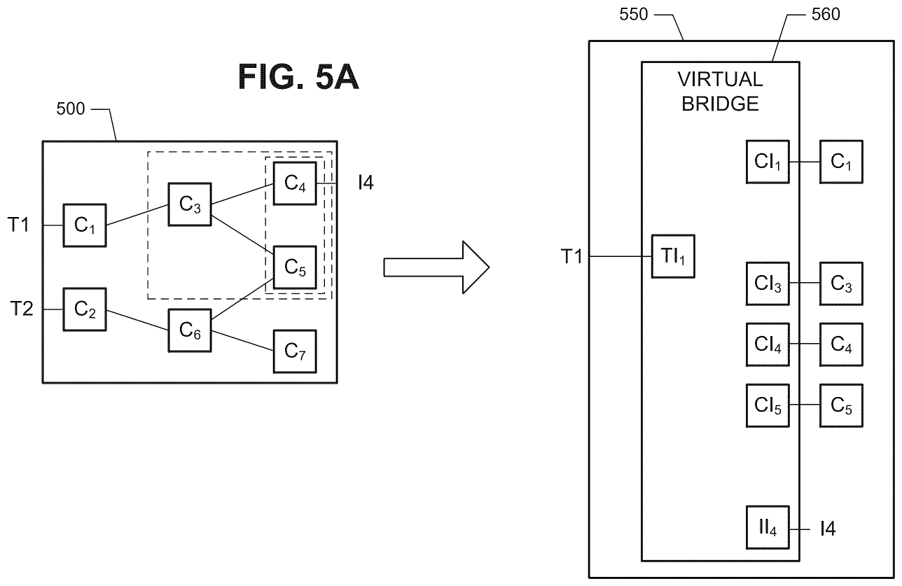

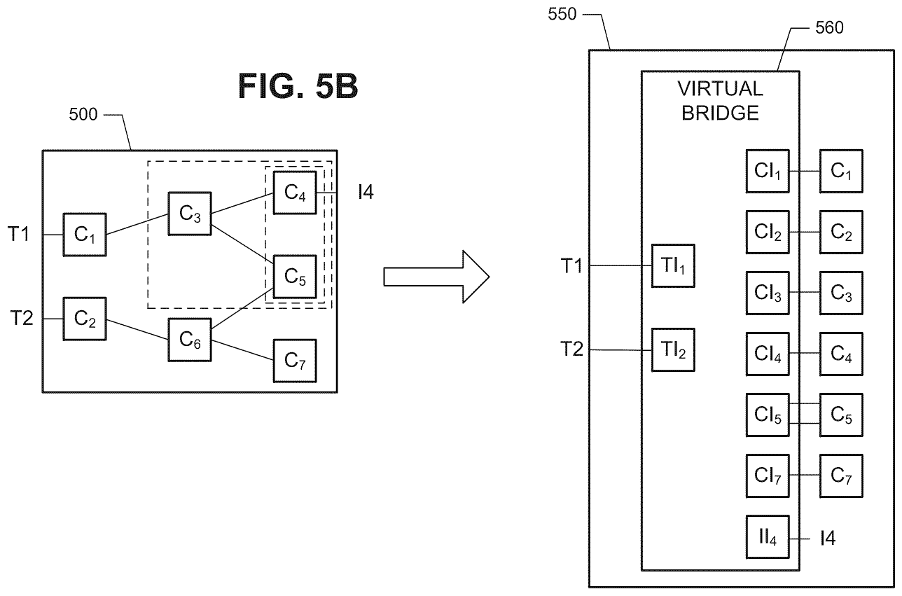

FIGS. 5A and 5B illustrate a simple design 500 and a virtual bridge platform 550 including a virtual bridge 560 that was created by applying the method of FIG. 3. The simple design 500 includes source buses T1 and T2, components C₁, C₂, C₃, C₄, C₅, C₆ and C₇, and bus interconnections (represented as lines) for connecting the source buses T1 and T2 and the components C₁, C₂, C₃, C₄, C₅, C₆ and C₇. Components C₁ to C₅ and C₇ are targeted. Component C₆ is not targeted, but rather serves as a pathway. In contrast to the simple design 500, a complex design may have many, many more components and interconnections, and many different levels of hierarchies.

Reference is made first to FIG. 5A. The method of FIG. 3 is started, whereby source bus T1 is selected. The source bus T1 is a target bus, so a target interface TI₁ is copied in the virtual bridge 560. Next, components C₁, C₃, C₄ and C₅ are in a visible path with the selected source bus T₁, so those components C₁, C₃, C₄ and C₅ are arranged outside of the virtual bridge 560, and their respective component interfaces CI₁, CI₃, CI₄ and CI₅ are copied into the virtual bridge 560.

For each path from the selected source bus T1 to a given component, transformations are translated into a subspace map and segment for that given component. The subspace map and segment are copied into the interface of the given component. References to the memory map, subspace map and segment of the given component are copied in the target interface TI₁.

Initiator 14 is at a boundary of component C₄, so an initiator interface II₄ is copied into the virtual bridge 560, and its transformations are translated into a subspace map and segment. Thus far, the method of FIG. 3 has produced the virtual bridge platform 550 shown in FIG. 5A.

Reference is now made to FIG. 5B. The source bus T2 is selected, and it is also target bus, so a target interface TI₂ is copied in the virtual bridge 560. Next, components C₂, C₆, C₇ and C₅ are in a visible path with the selected source bus T₂, but component C₆ is not targeted and processing for component C₅ has already been performed, so components C₂ and C₇ are added outside of the virtual bridge 560, and their respective component interfaces CI₂ and CI₇ are copied into the virtual bridge 560.

For each path from the selected source bus T2 to a given component, transformations are translated into a subspace map and segment for that given component. The subspace map and segment are copied into the interface of the given component. References to the memory map, subspace map and segment of the given component are copied in the target interface TI₂.

There being no additional source buses, the method of FIG. 3 is completed. Resulting is the virtual bridge platform 550 shown in FIG. 5B.

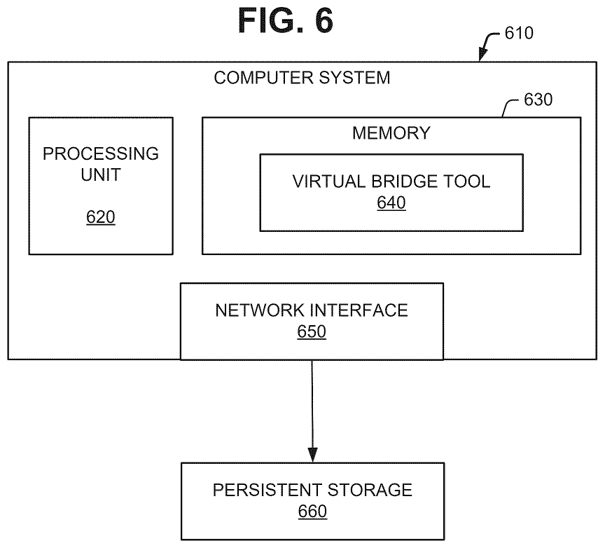

FIG. 6 shows a computer system 610 including a processing unit 620 and computer-readable memory 630 that stores a tool 640 for creating a virtual bridge from an IC design and a system-level address map. The tool 640, when executed by the processing unit 620, may perform some or all of the steps of FIG. 3. In some embodiments, the tool may be part of an electronic computer-aided design system that generates the design and the system-level address map.

The computer system 610 may further include a network interface 650 for transmitting exports that are generated by the tool 640. The exports may include an RTL design generated from the canonical model and the canonical model itself. The exports may be stored in external persistent storage 660 (e.g., a database, another computer system). The exports may also be saved in the memory 630 of the computer system 610.

Certain examples have been described herein and it will be noted that different combinations of different components from different examples may be possible. Salient features are presented to better explain examples; however, it is clear that certain features may be added, modified and/or omitted without modifying the functional aspects of these examples as described.

Certain methods according to the various aspects of the invention may be performed by instructions that are stored upon a non-transitory computer readable medium. The non-transitory computer readable medium stores code including instructions that, if executed by one or more processors, would cause a system or computer to perform steps of the method described herein. The non-transitory computer readable medium includes: a rotating magnetic disk, a rotating optical disk, a flash random access memory (RAM) chip, and other mechanically moving or solid-state storage media. Any type of computer-readable medium is appropriate for storing code comprising instructions according to various example.

Various examples are methods that use the behavior of either or a combination of machines. Method examples are complete wherever in the world most constituent steps occur. For example, IP elements or units include: processors (e.g., CPUs or GPUs), random-access memory (RAM—e.g., off-chip dynamic RAM or DRAM), a network interface for wired or wireless connections such as ethernet, WiFi, 3G, 4G long-term evolution (LTE), 5G, and other wireless interface standard radios. The IP may also include various I/O interface devices, as needed for different peripheral devices such as touch screen sensors, geolocation receivers, microphones, speakers, Bluetooth peripherals, and USB devices, such as keyboards and mice, among others. By executing instructions stored in RAM devices processors perform steps of methods as described herein.

Some examples are one or more non-transitory computer readable media arranged to store such instructions for methods described herein. Whatever machine holds non-transitory computer readable media comprising any of the necessary code may implement an example. Some examples may be implemented as: physical devices such as semiconductor chips; hardware description language representations of the logical or functional behavior of such devices; and one or more non-transitory computer readable media arranged to store such hardware description language representations. Descriptions herein reciting principles, aspects, and embodiments encompass both structural and functional equivalents thereof. Elements described herein as coupled have an effectual relationship realizable by a direct connection or indirectly with one or more other intervening elements.

Practitioners skilled in the art will recognize many modifications and variations. The modifications and variations include any relevant combination of the disclosed features. Descriptions herein reciting principles, aspects, and embodiments encompass both structural and functional equivalents thereof. Elements described herein as “coupled” or “communicatively coupled” have an effectual relationship realizable by a direct connection or indirect connection, which uses one or more other intervening elements. Embodiments described herein as “communicating” or “in communication with” another device, module, or elements include any form of communication or link and include an effectual relationship. For example, a communication link may be established using a wired connection, wireless protocols, near-filed protocols, or RFID.

To the extent that the terms “including”, “includes”, “having”, “has”, “with”, or variants thereof are used in either the detailed description and the claims, such terms are intended to be inclusive in a similar manner to the term “comprising.”

The scope of the invention, therefore, is not intended to be limited to the exemplary embodiments shown and described herein. Rather, the scope and spirit of present invention is embodied by the appended claims.

What is claimed is:

1. A computer-implemented design method comprising:
accessing an elaborated model of an integrated circuit, the elaborated model including a first plurality of source buses, a second plurality of addressable components, and a third plurality of interconnections between the source buses and the components;
generating a canonical model from the elaborated model, the canonical model including a source bus interface for each one of the source buses and a component interface for each one of the components, wherein the plurality of interconnections between the components and the sources are consolidated; and
generating exports from the canonical model instead of the elaborated model.

2. The method of claim 1, wherein the component interfaces are generated only for those components that are targeted.

3. The method of claim 1, wherein generating the canonical model includes generating memory map information for each of the component interfaces and references for each of the source bus interfaces, wherein the references provide links from the source bus interfaces to the component interfaces.

4. The method of claim 3, wherein generating the canonical model includes connecting each component to its corresponding component interface, and connecting each source bus to its corresponding source bus interface.

5. The method of claim 1, further comprising generating a system-level address map from the elaborated model; and using the system-level address map to locate the source buses and components in the elaborated model and identify transformations in the elaborated model.

6. The method of claim 1, wherein generating the canonical model includes:
selecting a source bus;
for each component in a path with the selected source bus:
copying an address space in a corresponding component interface; and
translating transformations along the path into a subspace map and segment and copying the subspace map and segment into the corresponding component interface; and
generating references to the subspace map and segment and copying the references in the source bus interface corresponding to the selected source bus.

7. The method of claim 6, wherein generating the canonical model further includes: copying an initiator interface for each initiator bus of a component, the initiator interface copied in the canonical model, the initiator interface including a subspace map and segment.

8. The method of claim 1, wherein the exports include an RTL design of the canonical model.

9. The method of claim 1, wherein the exports include the canonical model itself.

10. A computer system comprising:
a processing unit; and
computer-readable memory configured with a tool for causing the processing unit to generate a canonical model of an integrated circuit from an elaborated model of the integrated circuit; wherein the elaborated model includes source buses, addressable components, and interconnections; wherein the canonical model includes a virtual bridge, source bus interfaces connected to inputs of the virtual bridge, and the addressable components connected to outputs of the virtual bridge; and wherein the interconnections in the elaborated model are consolidated into the virtual bridge in the canonical model.

11. The system of claim 10, wherein the virtual bridge includes a source bus interface for each source bus and a component interface for each component.

12. The system of claim 11, wherein generation of the canonical model further includes connecting each component to its corresponding component interface, and connecting each source bus to its corresponding source bus interface.

13. The system of claim 12, wherein generation of the canonical model further includes generating memory map information in each of the component interfaces and references in each of the source bus interfaces, wherein the references provide links from the source bus interfaces to the component interfaces.

14. The system of claim 10, wherein the tool further causes the processing unit to generate a system-level address map from the elaborated model; and use the system-level address map to locate the source buses and the components in the elaborated model and also to identify transformations in the elaborated model.

15. The system of claim 10, wherein the tool further causes the processing unit to generate exports from the canonical model instead of the elaborated model.

16. An article comprising computer-readable memory encoded with instructions that, when executed, cause a processing unit to:
create a canonical model of an integrated circuit from an elaborated model of the integrated circuit, the elaborated model including source buses, addressable components, and interconnections, the canonical model including a single virtual bridge, the source buses, and the components; wherein each source bus is connected to an input of the virtual bridge, and each component is connected to an output of the virtual bridge; and wherein all of the interconnections in the elaborated model are consolidated into the virtual bridge in the canonical model.

17. The article of claim 16, wherein the virtual bridge includes a source bus interface for each source bus and a component interface for each component.

18. The article of claim 17, wherein generation of the canonical model further includes generating memory map information in each of the component interfaces and references in each of the source bus interfaces, wherein the references provide links from the source bus interfaces to the component interfaces.

19. The article of claim 18, wherein generation of the canonical model further includes connecting each component to its corresponding component interface, and connecting each source bus to its corresponding source bus interface.

20. The article of claim 16, wherein the instructions further cause the processing unit to generate exports from the canonical model instead of the elaborated model.
